(19) United States
(12) Patent Application Publication
(10) Pub. No.: US 2026/0363041 A1
(43) Pub. Date: Nov. 12, 2026

(54) MANUFACTURING METHOD OF THROUGH GLASS VIA SUBSTRATE

(71) Applicant: INGENTEC CORPORATION, Miaoli County (TW)

(72) Inventors: Ai-Sen LIU, Miaoli County (TW); Cheng-Yu CHUNG, Miaoli County (TW); Hsiang-An FENG, Miaoli County (TW); Ya-Li CHEN, Miaoli County (TW)

(21) Appl. No.: 19/450,764

(22) Filed: Jan. 16, 2026

(30) Foreign Application Priority Data
May 9, 2025 (TW) 114117628

(51) Int. Cl. H10W 20/00; H10W 20/20

(52) U.S. Cl. CPC H10W 20/0253; H10W 20/0261; H10W 20/222

(57) ABSTRACT

A manufacturing method of a through glass via substrate includes the following steps. A plurality of composite components are disposed on a metal plate, and then the metal plate is covered with a cover. A glass material is filled between the cover and the metal plate, and then a sintering process is processed to obtain a sintered substrate. The sintered substrate is polished to obtain the through glass via substrate. The metal plate has a plurality of recesses, each of the composite components is placed into each of the recesses, correspondingly.

### RELATED APPLICATIONS

This application claims priority to Taiwan Application Serial Number 114117628, filed May 09, 2025, which is herein incorporated by reference.

### BACKGROUND

### Technical Field

The present disclosure relates to a manufacturing method of a through glass via substrate. More particularly, the present disclosure relates to a manufacturing method of a through glass via substrate, which has high productive efficiency.

### Description of Related Art

With the development of electronic devices, the conventional through glass via substrate is frequently used as interposers in three-dimensional packaging, so that chips disposed on top side and bottom side of the conventional through glass via substrate electrically connect to each other through solid state metals formed in a plurality of through holes of the conventional through glass via substrate.

However, the conventional manufacturing method has complicated processes, which includes drilling through the substrate, sputtering a seed layer, coating a photoresist, metallization, removing the photoresist and performing surface treatments. Moreover, the photoresist coating process further includes exposure and development steps. Therefore, the conventional manufacturing method leads to the following disadvantages: (1) the sizes and shapes of the through holes are difficult to adjust; (2) the equipment and the number of staffs required for each process are high so as to increase productive costs; and (3) the complicated processes makes it difficult to improve productive efficiency.

In view of this, how to simplify the productive processes of the manufacturing method of the through glass via substrate to improve productive efficiency, and how to increase the freedom of adjusting the shapes of the through holes, which have become the goal that related industries strive for.

### SUMMARY

According to one aspect of the present disclosure, a manufacturing method of a through glass via substrate includes the following steps. A plurality of composite components are disposed on a metal plate, and then the metal plate is covered with a cover. A glass material is filled between the cover and the metal plate, and then a sintering process is processed to obtain a sintered substrate. The sintered substrate is polished to obtain the through glass via substrate. The metal plate has a plurality of recesses, each of the composite components is placed into each of the recesses, correspondingly. Each of the composite components has a ceramic layer and a metal portion, the metal portion is covered by the ceramic layer, and the sintered substrate has a first surface and a second surface which are opposite to each other, after the sintered substrate is polished, the metal portion of each of the composite components is exposed from the first surface and the second surface of the sintered substrate.

According to another aspect of the present disclosure, a manufacturing method of a through glass via substrate includes the following steps. A plurality of composite components are disposed on at plurality of metal plates, and then each of the metal plates is covered with a cover. A glass material is filled between each of the metal plates and the cover which are corresponding to each other, and then a sintering process is processed to obtain a plurality of sintered substrates. The sintered substrates are polished to obtain a plurality of polished substrates. The polished substrates are stacked to each other, and the composite components of the polished substrates which are adjacent to each other are aligned so as to obtain a through glass via substrate. Each of the metal plates has a plurality of recesses, each of the composite components is placed into each of the recesses, correspondingly. Each of the composite components has a ceramic layer and a metal portion, the metal portion is covered with the ceramic layer, and each of the sintered substrates has a first surface and a second surface which are opposite to each other, after the sintered substrates are polished, the metal portion of each of the composite components is exposed from the first surface and the second surface of each of the sintered substrates.

### BRIEF DESCRIPTION OF THE DRAWINGS

The present disclosure can be more fully understood by reading the following detailed description of the embodiment, with reference made to the accompanying drawings as follows:

FIG. 1 is a flow chart of a manufacturing method of a through glass via substrate according to first embodiment of the present disclosure.

FIG. 2A is a top schematic view of the structure in the step 110 of FIG. 1.

FIG. 2B is a cross-sectional schematic view of the composite components and the metal plate along line 2B-2B of FIG. 2A.

FIG. 3A is a top schematic view of the structure before processing the sintering process in the step 120 of FIG. 1.

FIG. 3B is a cross-sectional schematic view of the composite components, the metal plate, the cover and the glass material along 3B-3B of FIG. 3A.

FIG. 4A is a top schematic view of the structure after processing the sintering process in the step 120 of FIG. 1.

FIG. 4B is a cross-sectional schematic view of the metal plate, the cover and the sintered substrate along 4B-4B of FIG. 4A.

FIG. 5A is a top schematic view of the through glass via substrate produced by manufacturing method of the through glass via substrate of FIG. 1.

FIG. 5B is a cross-sectional schematic view of the through glass via substrate along 5B-5B of FIG. 5A.

FIG. 6A is a cross-sectional schematic view of another through glass via substrate produced by manufacturing method of the through glass via substrate of first embodiment.

FIG. 6B is a cross-sectional schematic view of the through glass via substrate along 6B-6B of FIG. 6A.

FIG. 7 is a flow chart of the manufacturing method of the through glass via substrate according to second embodiment of the present disclosure.

FIG. 8A is a top schematic view of the through glass via substrate produced by manufacturing method of the through glass via substrate of second embodiment.

FIG. 8B is a cross-sectional schematic view of the through glass via substrate along 8B-8B of FIG. 8A.

### DETAILED DESCRIPTION

A number of examples of the present disclosure will be described below with reference to the accompanying drawings. The following description will include many practical details in order to be clear and specific. The reader, however, should understand that those practical details are not intended to be restrictive of the scope of the invention; in other words, the practical details are not essential to some embodiments of the invention.

Besides, for the sake of simplicity of the drawings, some conventional or commonly used structures and elements are drawn only schematically in the drawings, and repeated elements may be indicated by the same reference numeral or similar reference numerals.

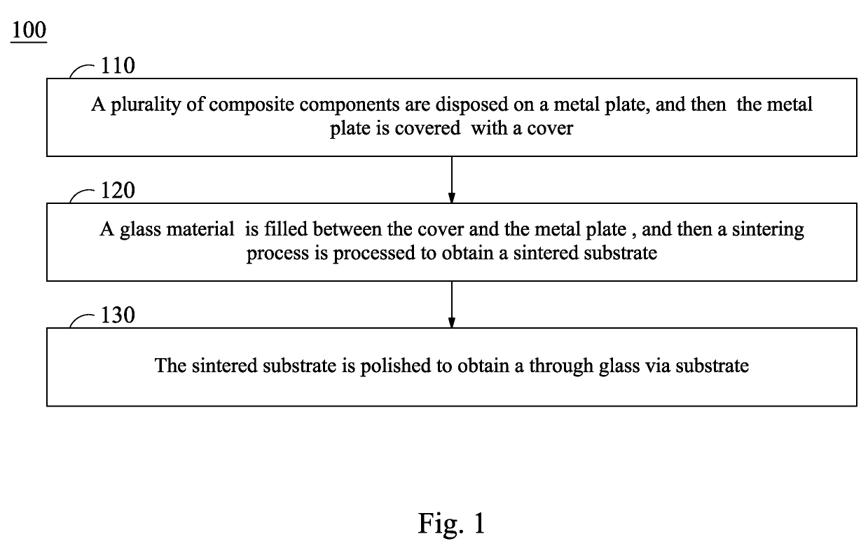

Please refer to FIG. 1, FIG. 1 is a flow chart of a manufacturing method of a through glass via substrate 100 according to first embodiment of the present disclosure. The manufacturing method of the through glass via substrate 100 includes step 110, step 120 and step 130.

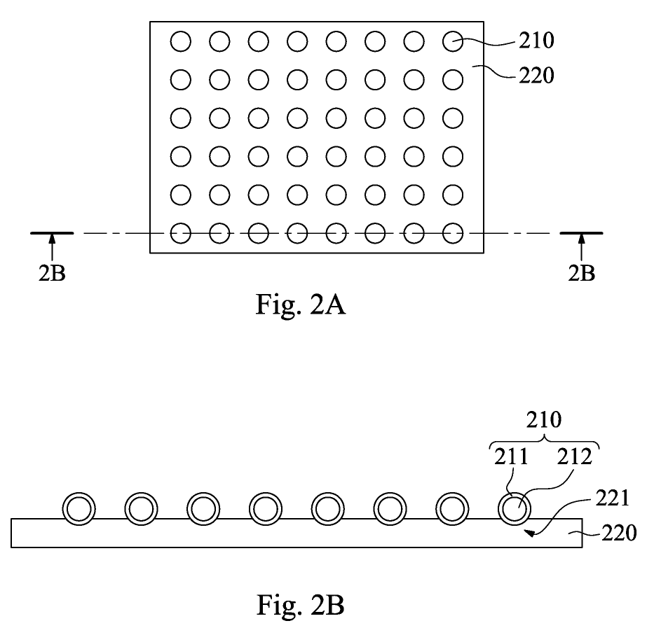

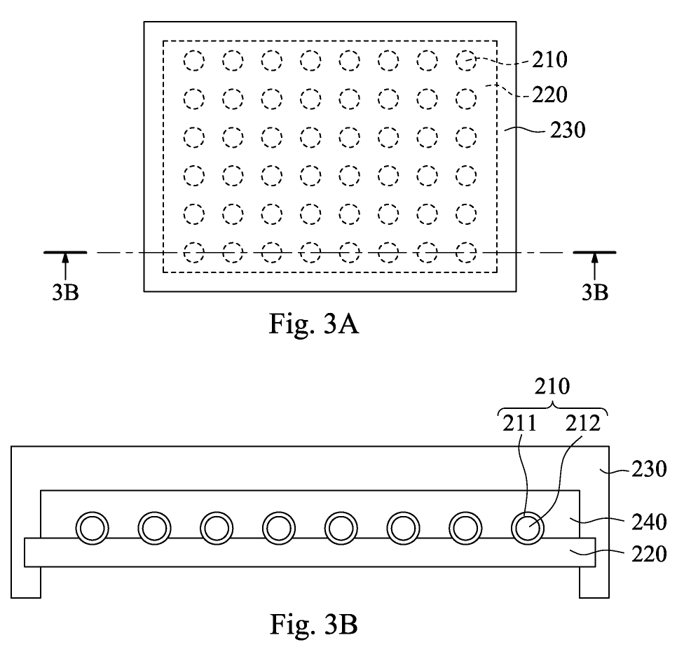

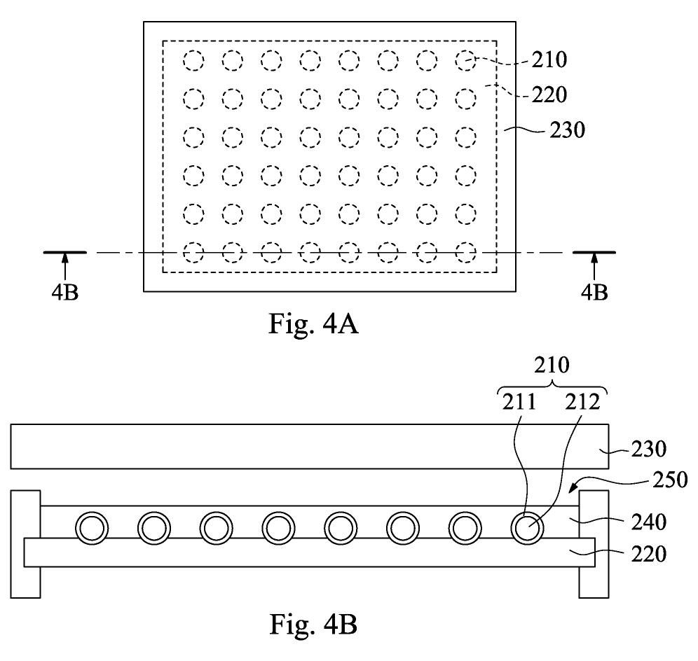

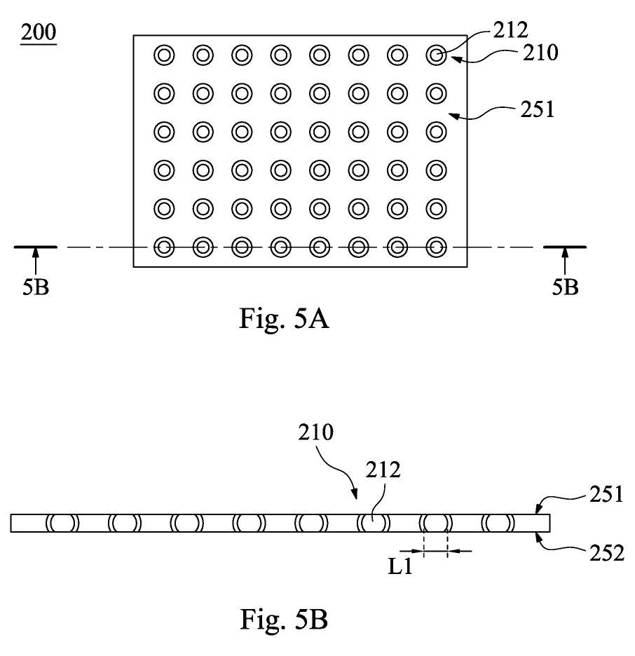

Please refer to FIGS. 2A, 2B, 3A, 3B, 4A, 4B, 5A, and 5B. FIG. 2A is a top schematic view of the structure in the step 110 of FIG. 1. FIG. 2B is a cross-sectional schematic view of the composite components 210 and the metal plate 220 along line 2B-2B of FIG. 2A. FIG. 3A is a top schematic view of the structure before processing the sintering process in the step 120 of FIG. 1. FIG. 3B is a cross-sectional schematic view of the composite components 210, the metal plate 220, the cover 230 and the glass material 240 along 3B-3B of FIG. 3A. FIG. 4A is a top schematic view of the structure after processing the sintering process in the step 120 of FIG. 1. FIG. 4B is a cross-sectional schematic view of the metal plate 220, the cover 230 and the sintered substrate 250 along 4B-4B of FIG. 4A. FIG. 5A is a top schematic view of the through glass via substrate 200 produced by manufacturing method of the through glass via substrate 100 of FIG. 1. FIG. 5B is a cross-sectional schematic view of the through glass via substrate 200 along 5B-5B of FIG. 5A.

As shown in FIGS. 2A, 2B, 3A, and 3B, in the step 110, a plurality of composite components 210 are disposed on a metal plate 220, and then the metal plate 220 is covered with a cover 230. The metal plate 220 has a plurality of recesses 221, each of the composite components 210 is placed into each of the recesses 221, correspondingly. Each of the composite components 210 has a ceramic layer 211 and a metal portion 212, the metal portion 212 is covered with the ceramic layer 211.

In the detail, each of the composite components 210 can be spherical so as to facilitate the composite components 210 naturally scrolling to the recesses 221, and the recesses 221 can be curved so as to dispose the composite components 210, correspondingly. However, the present disclosure is not limited herein.

As shown in FIGS. 4A and 4B, in the step 120, a glass material 240 is filled between the cover 230 and the metal plate 220, and then a sintering process is processed to obtain a sintered substrate 250. It should be noted that, after the sintering process, the glass material 240 can be shrunk and densified, so that the sintered substrate 250 can tightly cover the composite components 210. When the glass material 240 shrinks, the sintered substrate 250 separates from the cover 230 so as to facilitate subsequent demolding.

In the detail, in each of the composite components 210, the ceramic layer 211 covers the metal portion 212 to protect the metal portion 212. During sintering process, the metal material of the metal portion 212 is not easy to diffuse into the glass material 240 due to high temperature, thereby maintaining insulation of the glass material 240. Therefore, the metal portion 212 and other elements (its reference numeral is omitted) can form a good electrical connection.

A material of the ceramic layer 211 of each of the composite components 210 can include aluminum oxide, so that the ceramic layer 211 has higher thermal resistance to greatly protect the metal portion 212. Therefore, it is favorable to maintain the good structure of the composite components 210 during the sintering process.

A sintering temperature of the sintering process can be 500^{o}C to 600^{o}C. Thus, the glass material 240 can be formed, and it can avoid excessive energy consumption and be favorable to save productive costs.

The glass material 240 can include boron, so that the sintering temperature required by the glass material 240 can be reduce, it is facilitative to sinter the glass material 240, and it is favorable to save productive costs. Furthermore, the manufacturing method of a through glass via substrate 100 can be more simplified to improve the productive efficiency.

In the detail, during the sintering process, a pressure can be further provided to closely densify the glass material 240 so as to obtain the sintered substrate which is more close and densified.

As shown in FIGS. 5A and 5B, in the step 130, the sintered substrate 250 is polished to obtain the through glass via substrate 200. The sintered substrate 250 has a first surface 251 and a second surface 252 which are opposite to each other, after the sintered substrate 250 is polished, the metal portion 212 of each of the composite components 210 is exposed from the first surface 251 and the second surface 252 of the sintered substrate 250. Therefore, a good electrical connection between the through glass via substrate 200 and other elements can be formed via the metal portion 212.

In the other word, when the metal portion 212 of each of the composite components 210 is exposed from the first surface 251 and the second surface 252 of the sintered substrate 250, the metal portions 212 on the sintered substrate 250 can form a plurality of conductive portions which passes through the first surface 251 to the second surface 252, thereby providing the through glass via substrate 200 electrically connected to other elements.

A material of the metal portion 212 of each of the composite components 210 can include at least one of titanium nitride and aluminum nitride. Thus, the metal portion 212 can have good conductive and heat resistances, which is favorable to sinter the composite components 210, and the produced through glass via substrate 200 can form a good electrical connection with other elements.

A length L1 of each of the composite components 210 is 100 μm to 500 μm. Moreover, the length L1 of each of the composite components 210 is 300 μm to 400 μm. By controlling the length L1 of the composite components 210, the productive yield of the through glass via substrate 200 can be improve, and the produced through glass via substrate 200 can form a good electrical connection with other elements.

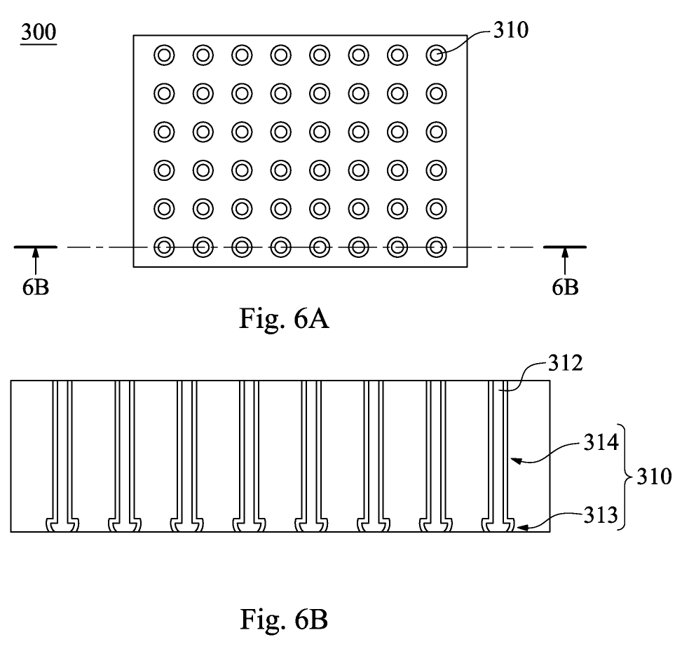

Please refer to FIGS. 6A and 6B. FIG. 6A is a cross-sectional schematic view of another through glass via substrate 300 produced by manufacturing method of the through glass via substrate 100 of first embodiment. FIG. 6B is a cross-sectional schematic view of the through glass via substrate 300 along 6B-6B of FIG. 6A.

Each of the composite components 310 can be rivet-shaped, and each of the composite components 310 has a head portion 313 and a rod portion 314, each of the head portions 313 is placed into each of the recesses (its reference numeral is omitted), correspondingly. Therefore, by adjusting the length of the rod portion 314, different thickness of the through glass via substrate 300 can be produced. Moreover, it is favorable for ensuring that the metal portion 312 can pass through the through glass via substrate 300 so as to facilitate the through glass via substrate 200 to form a good electrical connection with other elements.

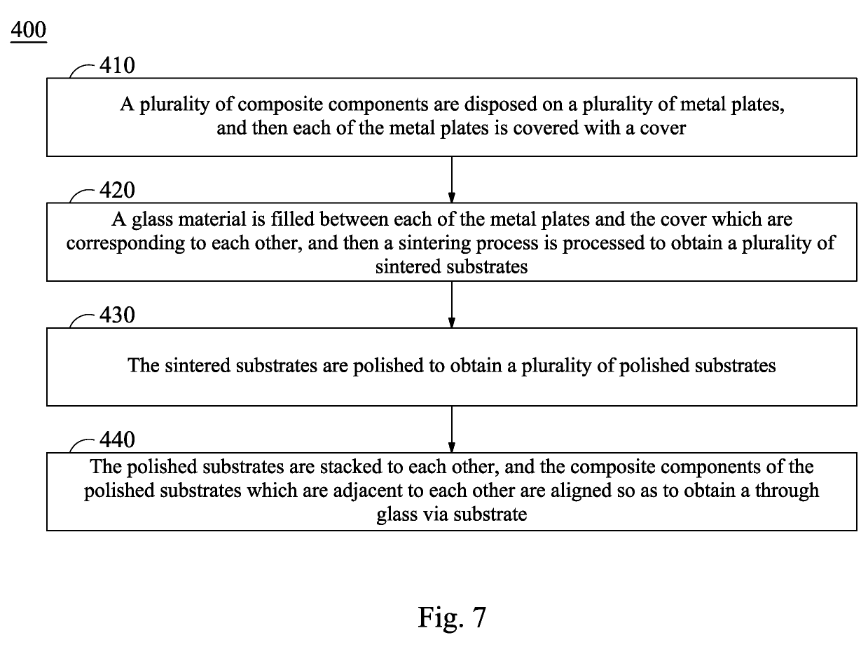

Please refer to FIG. 7. FIG. 7 is a flow chart of the manufacturing method of the through glass via substrate 400 according to second embodiment of the present disclosure. The manufacturing method of the through glass via substrate 400 includes step 410, step 420, step 430 and step 440. In the step 410, a plurality of composite components are disposed on at plurality of metal plates, and then each of the metal plates is covered with a cover.

In the step 420, a glass material is filled between each of the metal plates and the cover which are corresponding to each other, and then a sintering process is processed to obtain a plurality of sintered substrates. In the step 430, the sintered substrates are polished to obtain a plurality of polished substrates.

In the step 440, the polished substrates are stacked to each other, and the composite components of the polished substrates which are adjacent to each other are aligned so as to obtain a through glass via substrate.

Furthermore, each of the metal plates has a plurality of recesses, each of the composite components is placed into each of the recesses, correspondingly. Each of the composite components has a ceramic layer and a metal portion, the metal portion is covered with the ceramic layer, and each of the sintered substrates has a first surface and a second surface which are opposite to each other, after the sintered substrates are polished, the metal portion of each of the composite components is exposed from the first surface and the second surface of each of the sintered substrates.

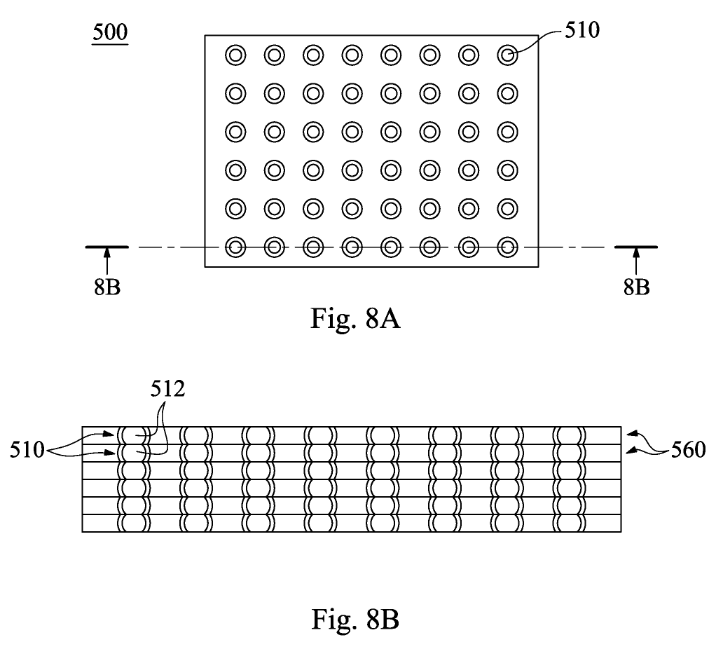

Please refer to FIGS. 8A and 8B. FIG. 8A is a top schematic view of the through glass via substrate 500 produced by manufacturing method of the through glass via substrate 400 of second embodiment. FIG. 8B is a cross-sectional schematic view of the through glass via substrate 500 along 8B-8B of FIG. 8A.

The through glass via substrate 500 is produced by manufacturing method of the through glass via substrate 400 of second embodiment. As shown in FIG. 8B, after the polished substrates 560 are aligned with and stacked to each other, the metal portion 512 of the composite components 510 are connected to each other, and the conductive portions which pass through the through glass via substrate 500 can be formed to provide the through glass via substrate 200 electrically connected to other elements.

In the detail, by changing the number of the polished substrates 560 stacked, aspect ratio of the conductive portions can be controlled, and the number of the polished substrates 560 stacked can be changed according to the industry demand, thereby improving the applied freedom of the through glass via substrate 500.

In the summary, according to the manufacturing method of the through glass via substrate of the present disclosure, due to setting the composite components, the sintered substrate already includes conductive metal portion, and then the through glass via substrate can be obtained by further polishing the sintered substrate. Moreover, different shapes of the composite components can be used to meet different structure demand. Therefore, it can eliminate conventional manufacturing processes such as seed layer sputtering, photoresist coating, and photoresist removal, thereby achieving the effects of simplified manufacturing process, high productive efficiency, and low productive cost.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A manufacturing method of a through glass via substrate, comprising:
disposing a plurality of composite components on a metal plate and then covering the metal plate with a cover;
filling a glass material between the cover and the metal plate and then processing a sintering process to obtain a sintered substrate; and
polishing the sintered substrate to obtain the through glass via substrate;
wherein the metal plate has a plurality of recesses, each of the composite components is placed into each of the recesses, correspondingly;
wherein each of the composite components has a ceramic layer and a metal portion, the metal portion is covered by the ceramic layer, and the sintered substrate has a first surface and a second surface which are opposite to each other, after the sintered substrate is polished, the metal portion of each of the composite components is exposed from the first surface and the second surface of the sintered substrate.

2. The manufacturing method of the through glass via substrate of claim 1, wherein each of the composite components is rivet-shaped, and each of the composite components has a head portion and a rod portion, each of the head portions is placed into each of the recesses, correspondingly.

3. The manufacturing method of the through glass via substrate of claim 1, wherein each of the composite components is spherical.

4. The manufacturing method of the through glass via substrate of claim 1, wherein a material of the metal portion of each of the composite components comprises at least one of titanium nitride and aluminum nitride.

5. The manufacturing method of the through glass via substrate of claim 1, wherein a length of each of the composite components is 100 μm to 500 μm.

6. The manufacturing method of the through glass via substrate of claim 5, wherein the length of each of the composite components is 300 μm to 400 μm.

7. The manufacturing method of the through glass via substrate of claim 1, wherein a material of the ceramic layer of each of the composite components comprises aluminum oxide.

8. The manufacturing method of the through glass via substrate of claim 1, wherein the glass material comprises boron.

9. The manufacturing method of the through glass via substrate of claim 1, wherein a sintering temperature of the sintering process is 500^{o}C to 600^{o}C.

10. The manufacturing method of the through glass via substrate of claim 1, wherein during the sintering process, a pressure is further provided to closely densify the glass material so as to obtain the sintered substrate.

11. A manufacturing method of a through glass via substrate, comprising:
disposing a plurality of composite components on a plurality of metal plates and then covering each of the metal plates with a cover;
filling a glass material between each of the metal plates and the cover which are corresponding to each other and then processing a sintering process to obtain a plurality of sintered substrates;
polishing the sintered substrates to obtain a plurality of polished substrates; and
stacking the polished substrates to each other, wherein the composite components of the polished substrates which are adjacent to each other are aligned so as to obtain a through glass via substrate;
wherein each of the metal plates has a plurality of recesses, each of the composite components is placed into each of the recesses, correspondingly;
wherein each of the composite components has a ceramic layer and a metal portion, the metal portion is covered with the ceramic layer, and each of the sintered substrates has a first surface and a second surface which are opposite to each other, after the sintered substrates are polished, the metal portion of each of the composite components is exposed from the first surface and the second surface of each of the sintered substrates.

12. The manufacturing method of the through glass via substrate of claim 11, wherein each of the composite components is rivet-shaped, and each of the composite components has a head portion and a rod portion, each of the head portions is placed into each of the recesses, correspondingly.

13. The manufacturing method of the through glass via substrate of claim 11, wherein each of the composite components is spherical.

14. The manufacturing method of the through glass via substrate of claim 11, wherein a material of the metal portion of each of the composite components comprises at least one of titanium nitride and aluminum nitride.

15. The manufacturing method of the through glass via substrate of claim 11, wherein a length of each of the composite components is 100 μm to 500 μm.

16. The manufacturing method of the through glass via substrate of claim 15, wherein the length of each of the composite components is 300 μm to 400 μm.

17. The manufacturing method of the through glass via substrate of claim 11, wherein a material of the ceramic layer of each of the composite components comprises aluminum oxide.

18. The manufacturing method of the through glass via substrate of claim 11, wherein the glass material comprises boron.

19. The manufacturing method of the through glass via substrate of claim 11, wherein a sintering temperature of the sintering process is 500^{o}C to 600^{o}C.

20. The manufacturing method of the through glass via substrate of claim 11, wherein during the sintering process, a pressure is further provided to closely densify the glass material so as to obtain the sintered substrate.
